(19) United States
(12) Patent Application Publication
(10) Pub. No.: US 2025/0389018 A1
(43) Pub. Date: Dec. 25, 2025

(54) SILICON CARBONITRIDE FILM-FORMING METHOD AND PLASMA PROCESSING APPARATUS

(71) Applicant: Tokyo Electron Limited, Tokyo (JP)

(72) Inventors: Haruhiko FURUYA, Yamanashi (JP); Jinwang LI, Yamanashi (JP); Nobuo MATSUKI, Yamanashi (JP)

(21) Appl. No.: 19/313,069

(22) Filed: Aug. 28, 2025

Related U.S. Application Data
(63) Continuation of application No. PCT/JP2024/009913, filed on Mar. 14, 2024.

(30) Foreign Application Priority Data
Mar. 28, 2023 (JP) 2023-050889

(51) Int. Cl. C23C 16/455; C23C 16/44; H01L 21/02

(52) U.S. Cl. CPC C23C 16/45542; C23C 16/4408; C23C 16/45553; C23C 16/45557; H01L 21/0217; H01L 21/02274; H01L 21/0228

(57) ABSTRACT

A silicon carbonitride film-forming method includes (a) providing a substrate in a processing chamber; (b) supplying, into the processing chamber, a first gas containing a precursor gas having an Si—N bond and an Si—C bond, thereby forming an adsorption layer over the substrate; (c) first purging of purging an interior of the processing chamber after (b); and (d) supplying, into the processing chamber, a second gas containing a hydrogen gas and power of VHF waves or UHF waves, thereby generating a plasma; and (e) second purging of purging the interior of the processing chamber after (d). (b) to (e) are repeatedly performed.

### CROSS-REFERENCE TO RELATED APPLICATIONS

This application is a continuation application of International Application No. PCT/JP2024/009913, filed on Mar. 14, 2024, and designated the U.S., which is based upon and claims priority to Japanese Patent Application No. 2023-050889, filed on Mar. 28, 2023, the entire contents of which are incorporated herein by reference.

### BACKGROUND

### 1. Field of the Invention

The present disclosure relates to a silicon carbonitride (SiCN) film-forming method and a plasma processing apparatus.

### 2. Description of the Related Art

For example, U.S. Patent Application Publication No. 2012/0122302 discloses a method for depositing a silicon carbide film over a substrate surface. The disclosed method includes, for example, using a vapor-phase carbosilane precursor, and employs a plasma enhanced atomic layer deposition (PEALD) process through atomic layer deposition (ALD). Also, U.S. Patent Application Publication No. 2012/0122302 describes that this method can be performed at a temperature lower than 600° C., e.g., between about 23° C. and about 200° C., or at about 100° C.

For example, Japanese Laid-Open Patent Application Publication Nos. 2014-013888 and 2015-15465 disclose a method for forming a silicon-containing film using a deposition method selected from an ALD deposition process and a cyclic CVD deposition process. The disclosed method includes providing a substrate in a reactor, and repeating a process including heating the substrate to, for example, 700° C. to introduce at least one silane-based precursor having an Si—N bond, an Si—Si bond, and an Si—H₂ group, purging the reactor to remove unreacted materials, providing a reducing agent (hydrogen plasma) for reaction with the precursor to deposit a silicon-containing film, and purging the reactor to remove unreacted materials.

For example, Japanese Laid-Open Patent Application Publication No. 2015-507362 discloses a method for forming a silicon nitride film over a substrate at a low temperature. The disclosed method includes supplying a gas containing a precursor gas molecule having an unstable Si—N bond, Si—C bond, or N—C bond, and preferentially cleaving the unstable bond to form a precursor material layer over the substrate. In the disclosure of Japanese Laid-Open Patent Application Publication No. 2015-507362, when forming the precursor material layer over the substrate, an activated precursor gas molecule is bonded to the surface of the substrate at one or more reactive sites, and a plasma processing process is performed on the precursor material layer to form a conformal silicon nitride film.

### SUMMARY

According to an aspect of the present disclosure, a silicon carbonitride film-forming method includes: (a) providing a substrate in a processing chamber; (b) supplying, into the processing chamber, a first gas containing a precursor gas having an Si—N bond and an Si—C bond, thereby forming an adsorption layer over the substrate, wherein the Si—N bond and the Si—C bond are not activated in the formation of the adsorption layer; (c) first purging of purging an interior of the processing chamber after (b); and (d) supplying, into the processing chamber, a second gas containing a hydrogen gas and power of VHF waves or UHF waves, thereby generating a plasma, wherein the substrate is exposed to the plasma and reacts with the adsorption layer to form a silicon carbonitride (SiCN) film, and at least one of the Si—C bond or the Si—N bond of the adsorption layer is introduced into the SiCN film; and (e) second purging of purging the interior of the processing chamber after (d). (b) to (e) are repeatedly performed.

### BRIEF DESCRIPTION OF THE DRAWINGS

FIG. 1 is a cross-sectional schematic diagram illustrating an example of a configuration of a plasma processing apparatus according to an embodiment of the present disclosure.

FIG. 2A is a diagram describing a precursor gas having an Si—C bond.

FIG. 2B is a diagram describing introduction of the Si—C bond into a film.

FIG. 3A is a diagram illustrating an example of the precursor gas.

FIG. 3B is a diagram illustrating an example of the precursor gas.

FIG. 3C is a diagram illustrating an example of the precursor gas.

FIG. 3D is a diagram illustrating an example of the precursor gas.

FIG. 3E is a diagram illustrating an example of the precursor gas.

FIG. 3F is a diagram illustrating an example of the precursor gas.

FIG. 3G is a diagram illustrating an example of the precursor gas.

FIG. 4 is a flowchart illustrating an example of an SiCN film-forming method according to an embodiment of the present disclosure.

FIG. 5A is a diagram illustrating an example of the SiCN film-forming method according to the embodiment.

FIG. 5B is a diagram illustrating a modified example of the SiCN film-forming method according to the embodiment.

FIG. 6 is a diagram illustrating an example of compositions of SiCN films and experimental results of pressure dependencies.

FIG. 7 is a diagram illustrating a relationship between a carbon concentration of the SiCN films and a film density of the SiCN films.

FIG. 8 is a diagram illustrating XPS measurement results of the SiCN films.

FIG. 9 is a diagram illustrating an example of experimental results obtained by use of an H₂ plasma and an N₂ plasma.

FIG. 10 is a flowchart illustrating an example of an SiCN film-forming method used in an experiment.

FIG. 11 is a diagram illustrating an example of an SiCN film-forming method used in an experiment.

FIG. 12 is a diagram illustrating a relationship between a carbon concentration of the SiCN films and a film density of the SiCN films in experimental results.

### DETAILED DESCRIPTION OF THE DISCLOSURE

The present disclosure provides a technique that can introduce an Si—C bond of a precursor gas into a film formed over a substrate.

Hereinafter, embodiments of the present disclosure will be described with reference to the drawings. In the drawings, the same components are denoted by the same reference symbols, and thus duplicate description thereof may be omitted.

### [Plasma Processing Apparatus]

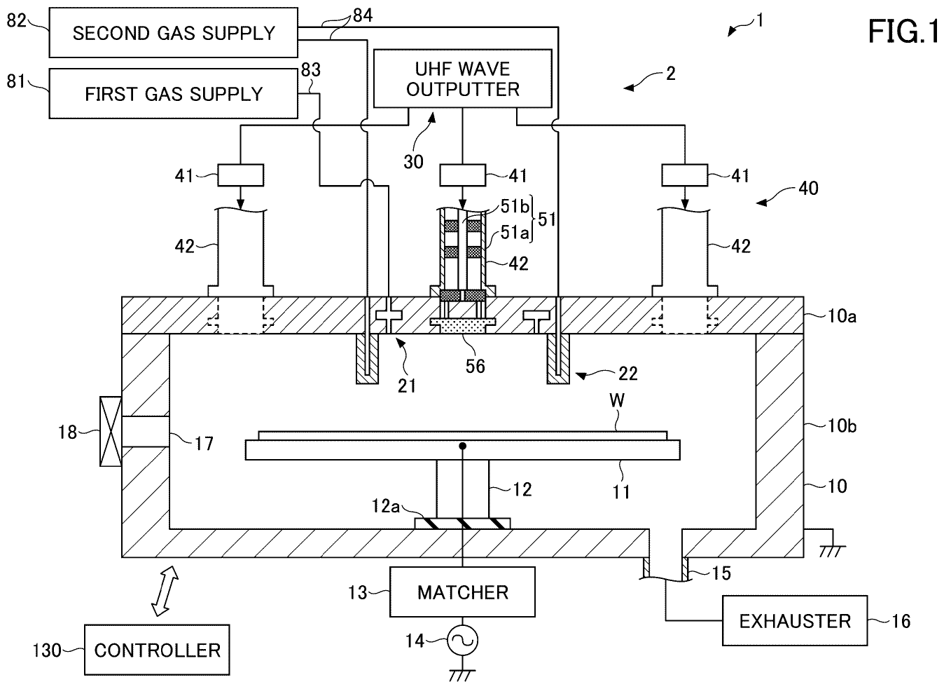

A configuration example of a plasma processing apparatus configured to perform the film-forming method according to the present embodiment will be described with reference to FIG. 1. FIG. 1 is a cross-sectional schematic diagram illustrating a configuration example of a plasma processing apparatus 1 including a UHF wave plasma source according to an embodiment of the present disclosure.

The plasma processing apparatus 1 includes a processing chamber 10 and a plasma source 2. The processing chamber 10 is configured to be airtight, and is formed of a metal material, such as aluminum or the like. Also, the processing chamber 10 has a substantially cylindrical shape, and is grounded. The plasma source 2 is configured to form a plasma by introducing UHF wave power into the processing chamber 10. A top wall 10a of the processing chamber 10 includes a metal body and dielectric members (hereinafter referred to as dielectric windows 56) that are fitted into the metal body and connected to a plurality of radiators 42. By this, the plasma source 2 introduces UHF waves into the processing chamber 10 through the plurality of dielectric windows 56 in the top wall 10a.

However, the configuration of the top wall 10a of the processing chamber 10 is not limited to the configuration including the metal body and the dielectric members that are fitted into the metal body and connected to the plurality of radiators 42. In one exemplary configuration, a dielectric member may be provided to cover the surface of the top wall 10a facing the substrate W, and the power of UHF waves may be introduced from the single radiator 42. In another exemplary configuration, the surface of the top wall 10a facing the substrate W may be provided with a showering structure configured to supply a predetermined gas in the form of shower. Also, the power introduced into the processing chamber 10 is not limited to UHF waves, but may be VHF waves. The frequency of the VHF waves or the UHF waves is 100 MHz or higher and 3 GHZ or lower.

The plasma processing apparatus 1 includes a controller 130. The controller 130 is, for example, a computer, and includes a program storage (not shown). The program storage stores a program for controlling processing of the substrate W, e.g., a semiconductor wafer, in the plasma processing apparatus 1. The program may be previously recorded in a computer-readable storage medium, such as a computer-readable hard disk (HD), a flexible disk (FD), a compact disk (CD), a magneto-optical disk (MO), a memory card, or the like, and may be installed in the controller 130 from that storage medium.

In the processing chamber 10, a stage 11 configured to support the substrate W horizontally is provided in a state of being supported by a cylindrical support 12 that is provided upright, from an insulating member 12a, at the center of the bottom of the processing chamber 10. Materials forming the stage 11 and the support 12 are, for example, a metal, such as aluminum having an anodized surface, or an insulating material (e.g., ceramics) including an electrode for high frequency in the insulating material.

Although not illustrated, the stage 11 is provided, for example, with a temperature controller, a gas flow path through which a gas for heat transfer is supplied to the rear surface of the substrate W, and raising and lowering pins configured to rise and descend for transferring the substrate W. Further, the stage 11 may be provided with an electrostatic chuck configured to electrostatically adsorb the substrate W.

An RF bias power supply 14 is electrically connected to the stage 11 through a matcher 13. When RF bias power is supplied from the RF bias power supply 14 to the stage 11, ions in the plasma are attracted to the substrate W, thereby contributing to an improvement in film quality and in-plane uniformity.

An exhaust tube 15 is connected to the bottom of the processing chamber 10 at a position closer to a side wall 10b, and an exhauster 16 including a vacuum pump is connected to the exhaust tube 15. By driving the exhauster 16, it is possible to exhaust the internal gas of the processing chamber 10, and reduce the internal pressure of the processing chamber 10 to a predetermined pressure. The side wall 10b of the processing chamber 10 is provided with a transfer opening 17 for transfer of the substrate W, and a gate valve 18 configured to open and close the transfer opening 17.

The plasma processing apparatus 1 includes a first gas shower 21 configured to discharge a predetermined gas into the processing chamber 10 from the top wall 10a of the processing chamber 10, and a second gas shower 22 configured to introduce gas from a position between the top wall 10a and the stage 11.

For the sake of convenience, the first gas shower 21 and the second gas shower 22 are illustrated at positions shifted in a radial direction in FIG. 1. However, the first gas shower 21 and the second gas shower 22 are alternately provided on the same circle. The first gas shower 21 supplies, from the rear surface of the top wall 10a, the gas delivered from a first gas supply 81 through a gas line 83. The second gas shower 22 includes a nozzle hanging from the rear surface of the top wall of the processing chamber 10, and supplies, from the tip of the nozzle to a position between the top wall 10a and the stage 11, the gas delivered from a second gas supply 82 through a gas line 84.

The plasma source 2 includes a UHF wave outputter 30 configured to distribute and output UHF waves through a plurality of paths, and a UHF wave transmitter 40 configured to transmit the UHF waves output from the UHF wave outputter 30. The UHF wave outputter 30 includes a UHF wave power supply, a UHF wave oscillator, an amplifier, and a distributor. The UHF wave power supply is configured to supply power to the UHF wave oscillator. The UHF wave oscillator is configured to cause, for example, PLL oscillation of UHF waves having a predetermined frequency. The amplifier is configured to amplify the oscillated UHF waves. The distributor is configured to distribute the UHF waves amplified by the amplifier while matching the impedance on the input side with the impedance on the output side so as to minimize loss of the UHF waves. The frequency of the UHF waves is 300 MHz or higher and 3 GHZ or lower.

The UHF wave transmitter 40 includes a plurality of amplifiers 41, and the plurality of radiators 42 provided to correspond to the plurality of amplifiers 41. For example, a total of seven of the radiators 42 are disposed, i.e., one of the radiators 42 is disposed at the center of the top wall 10a, and six of the radiators 42 are disposed at equal intervals on a circumference centered on the central radiator 42. In this example, the radiators 42 are disposed such that distances between the central radiator 42 and the circumferential radiators 42 are equal to distances between the circumferential radiators 42.

The amplifiers 41 are configured to guide the UHF waves, distributed by the distributor, to the corresponding radiators 42. Each radiator 42 includes a coaxial tube 51. The coaxial tube 51 includes a coaxial UHF wave transmission path formed by a cylindrical outer conductor 51a and a rod-shaped inner conductor 51b provided at the center of the cylindrical outer conductor 51a. The radiator 42 includes a power supply antenna (not shown) configured to supply the UHF waves, amplified by the amplifier 41, to the coaxial tube 51. Further, the radiator 42 includes a tuner configured to match impedance of a load with characteristic impedance of the UHF wave power supply, and an antenna configured to radiate the UHF waves from the coaxial tube into the processing chamber 10.

The antenna is provided at a lower end of the coaxial tube 51, and fitted into a metal portion of the top wall 10a of the processing chamber 10. The antenna includes the dielectric window 56, and the UHF waves transmitted through the dielectric window 56 generate a surface wave plasma in a portion directly below the dielectric window 56 in the processing chamber 10.

The plurality of the dielectric windows 56 are provided such that one of the dielectric windows 56 is disposed at the center of a ceiling and six of the dielectric windows 56 are disposed at an outer circumferential portion. Among the plurality of the dielectric windows 56, each can independently control the UHF wave power supplied from the plasma source 2. The UHF wave power supplied from the dielectric windows 56 at the outer circumferential portion may be higher than or equal to the UHF wave power supplied from the central dielectric window 56.

The plasma processing apparatus 1 may have an ion trap function in the processing chamber 10, and may irradiate a substrate with hydrogen radicals in the case of a hydrogen plasma (H₂ plasma) described below.

### [Outline of SiCN Film Formation]

In the SiCN film-forming method of the present disclosure, a plasma enhanced atomic layer deposition (PEALD) process through ALD is performed in the plasma processing apparatus 1.

A precursor gas, i.e., a raw material gas, is supplied from the second gas shower 22. For example, when forming an SiCN film, a first gas containing a precursor gas having an Si—N bond and an Si—C bond is supplied from the second gas shower 22 to form an adsorption layer over the substrate W. In an adsorption layer-forming step, no plasma is used, due to no power being supplied. Dissociation of the precursor gas is suppressed by supplying the precursor gas to a position closer to the substrate W. Thus, the precursor gas is adsorbed onto the substrate W. In the adsorption layer-forming step, the Si—N bond and the Si—C bond are not activated. Therefore, the Si—N bond and the Si—C bond of the adsorption layer are not cleaved.

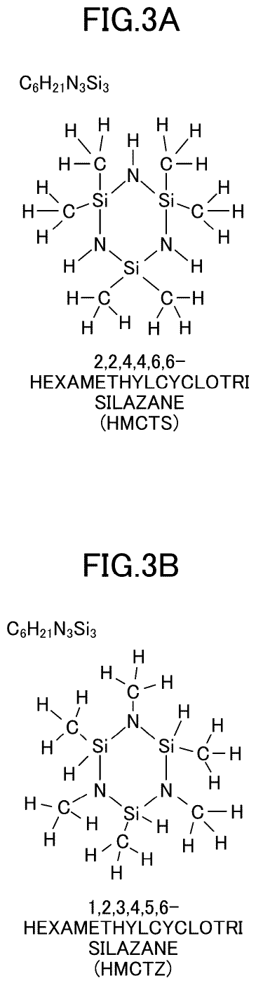

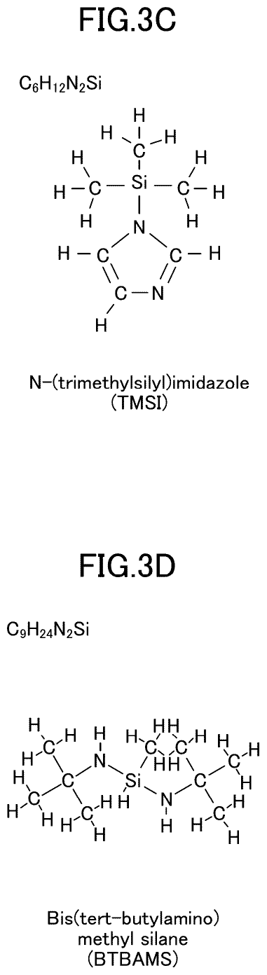

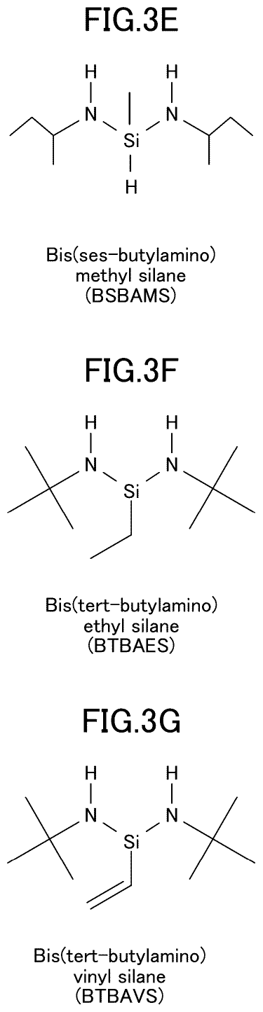

The precursor gas may be HMCTS, HMCTZ, TMSI, BTBAMS, BSBAMS, BTBAES, or BTBAVS (see FIGS. 3A to 3G). The precursor gas may have at least the Si—N bond and the Si—C bond, and may be free of an Si—Si bond.

The first gas may contain a carrier gas, such as an He gas or the like. The first gas may contain an inert gas, such as an Ar gas or the like, as a dilution gas. The carrier gas and the dilution gas contained in the first gas may be supplied from the first gas shower 21. However, the dilution gas contained in the first gas may be supplied from the second gas shower 22.

A second gas containing an H₂ gas (hydrogen gas) is supplied from the first gas shower 21. The H₂ gas is activated by a plasma (plasma-excited) by supply of the UHF wave power. Optionally, the RF bias power may be supplied from the RF bias power supply 14. Carbon (C) other than the C of the Si—C bond contained in the precursor gas is in a moiety R that is readily cleaved from Si. When the substrate W is exposed to the plasma-excited H₂ gas (H₂ plasma) for reaction with the adsorption layer, the H₂ plasma can cleave the bond of the moiety R. By this, at least one of the Si—N bond or the Si—C bond of the adsorption layer can be introduced into the SiCN film, while eliminating the moiety R, which can degrade properties of the SiCN film, from the adsorption layer. According to this method, it is possible to form the SiCN film in a state in which the temperature of the substrate W is controlled to be a low temperature of 450° C. or lower, and improve film quality by introduction of the Si—C bond into the SiCN film.

The second gas may contain an inert gas. The inert gas may be at least one of an Ar gas, an He gas, or an N₂ gas. The inert gas contained in the second gas may be supplied from the first gas shower 21 and/or the second gas shower 22.

A purge step is included between: supplying the first gas containing the precursor gas to form the adsorption layer over the substrate W; and supplying the second gas containing the H₂ gas to expose the substrate W to the H₂ plasma for reaction with the adsorption layer to form the SiCN film.

In the purge step, an inert gas, such as an Ar gas or the like, is supplied from the first gas shower 21 and/or the second gas shower 22. The purge step performed before supplying the first gas containing the precursor gas into the processing chamber 10 to form the adsorption layer over the substrate W (hereinafter referred to as “adsorption layer-forming step”) is referred to as a second purge step. A purge step performed before supplying the second gas containing the H₂ gas to expose the substrate W to the H₂ plasma for reaction with the adsorption layer to form the SiCN film (hereinafter referred to as “SiCN film-forming step”) yet after the adsorption layer-forming step is referred to as a first purge step.

In the first purge step or the second purge step, the gas in the processing chamber 10 is substituted by supply of an Ar gas or the like, and the gas supplied in a previous step is exhausted by the exhauster 16 to the exterior of the processing chamber 10.

The first purge step, the adsorption layer-forming step, the second purge step, and the SiCN film-forming step are repeatedly performed. Thus, the SiCN film can be formed over the substrate W through ALD using the plasma processing apparatus 1 illustrated in FIG. 1, with the substrate W being controlled to be a temperature of 450° C. or lower.

### [Low-Temperature Formation of SiCN Film]

An SiN film is scraped when exposed to an etching solution, such as hydrofluoric acid or the like, used in the production process of electronic devices. Therefore, in recent years, an SiCN film has been used as a film having high resistance to wet etching in the production process of electronic devices. Especially, as the integration density of devices increases, an SiCN film having high resistance to wet etching is required to be formed at a low temperature (e.g., 450° C. or lower).

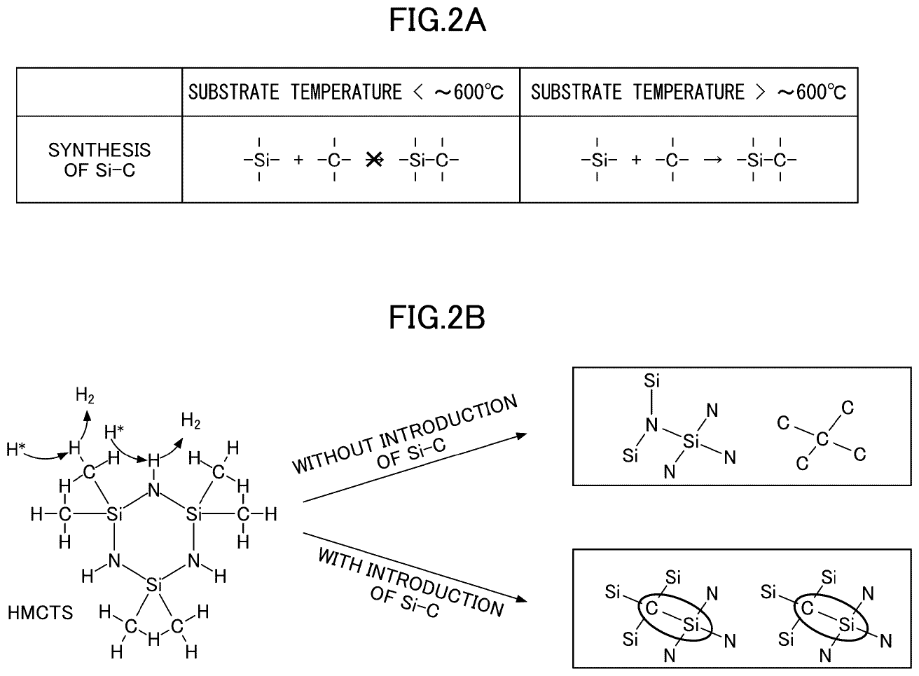

As illustrated on the right side of FIG. 2A, when the substrate temperature during film formation is 600° C. or higher, Si contained in the gas is bonded to C to form an Si—C bond during the film formation. This can form a desired SiCN film having improved film quality.

As illustrated on the left side of FIG. 2A, when the substrate temperature during film formation is lower than 600° C. (e.g., 450° C.), Si contained in the gas is preferentially bonded to N in the processing chamber 10. Therefore, it is challenging to bind Si to C at a low temperature, and thus synthesis of an Si—C bond does not proceed at a low temperature. This cannot form a desired SiCN film, and cannot improve film quality. Especially, a plasma cleaves the Si—C bond by ion energy, and eventually, there is no carbon (C) in the composition of the adsorption layer, resulting in substantially forming an SiN film.

Therefore, according to the SiCN film-forming method of the present embodiment, the precursor gas having the Si—C bond is used to introduce the Si—C bond into the SiCN film without cleaving the Si—C bond of the precursor gas. Further, the precursor gas having the Si—N bond in addition to the Si—C bond is used to introduce the Si—N bond into the SiCN film without cleaving the Si—N bond of the precursor gas. For introducing the Si—C bond and the Si—N bond in the precursor gas into the SiCN film, a raw material gas having features (1) to (3) below is used as the precursor gas:
(1) an Si—C bond is contained;
(2) an Si—N bond is contained; and
(3) carbon (C) other than the C contained in the Si—C bond and the Si—N bond is in a moiety that is readily cleaved from Si (hereinafter this moiety may be referred to as the moiety R, such as “R”, “R′”, or the like).

Regarding (3), for example, the C other than the C contained in the Si—C bond and the Si—N bond is in “R” and “R′” of Si—NH—R, Si—NR₂, and Si—NRR′. For example, a moiety (e.g., CH₃) containing carbon having an adverse effect on the SiCN film is in the moiety R that is readily cleaved from Si.

The binding energy of Si—N is about 400 KJ/mol, and the binding energy of N—R of Si—NH—R is about 200 KJ/mol to about 300 KJ/mol. Thus, N—R is more readily cleaved than in Si—N. Therefore, Si—N of Si—NH—R remains due to the reaction of the adsorption layer with an H₂ plasma, and R is cleaved to achieve introduction of the Si—C bond and the Si—N bond and removal of the C in the moiety R having an adverse effect on the SiCN film.

When the Si—C bond is not introduced, as illustrated in the right-upper diagram of FIG. 2B, the adsorption layer does not contain the Si—C bond, and the SiCN film cannot be formed with the temperature of the substrate W being controlled to be a temperature of 450° C. or lower. Conversely, when the Si—C bond is introduced, as illustrated in the right-lower diagram of FIG. 2B, the adsorption layer contains the Si—C bond, and the SiCN film having high film quality can be formed. The film quality can be further improved by use of a high-frequency plasma having a high plasma density, using the plasma processing apparatus 1 illustrated in FIG. 1. For improving the film quality by use of the high-density plasma, a high-frequency plasma generated by VHF waves or UHF waves having a frequency of 100 MHz or higher and 3 GHz or lower is used.

As described above, according to the SiCN film-forming method of the present embodiment, the Si—C bond of the adsorption layer is introduced into the SiCN film. The Si—N bond of the adsorption layer is also introduced into the SiCN film. According to this method, an SiCN film having a high density and a high etching resistance can be formed with the temperature of the substrate W being controlled to be 450° C. or lower.

Examples of the precursor gas having the above features (1) to (3) are as follows.

### Aminosilanes:

R^{I}R^{II}N—R₂₋ₓSiHₓ—NR^{III}R^{IV}, in which x is an integer of 0 or 1, R is a CₙHₘ group, and R^{I}, R^{II}, R^{III}, and R^{IV} are the same or different CₙHₘ groups, or are H. R^{I}, R^{II}, R^{III}, and R^{IV} are examples of the moiety R containing carbon (C) other than the C contained in the Si—C bond and the Si—N bond that is readily cleaved from Si.

### Silazanes:

cyclic [—(CH₃)₂Si—NH—]ₙ, cyclic [—(CH₃)SiH—NH—]ₙ, and cyclic [—(CH₃)SiH—N(CH₃)—]ₙ, in which, for example, n=4 or greater and 6 or less.

2,2,4,4,6,6-Hexamethylcyclotrisilazane (see HMCTS in FIG. 3A), linear (CH₃)₃Si—NH—Si(CH₃)₃, (CH₃)₃Si—[NH—Si(CH₃)₂]ₙ—Si(CH₃)₃ in which, for example n=1 or greater and 3 or less, are examples of the precursor gas containing the Si—C bond and the Si—N bond. As long as the Si—C bond is contained, some or all of the CH₃ may be changed to H or CₓH_{y}.

### Silyl Imidazoles:

Trimethylsilylimidazole (see TMSI in FIG. 3C).

The precursor gas may be HMCTS (FIG. 3A), HMCTZ (FIG. 3B), TMSI (FIG. 3C), BTBAMS (FIG. 3D), BSBAMS (FIG. 3E), BTBAES (FIG. 3F), or BTBAVS (FIG. 3G).

### [SiCN Film-Forming Method]

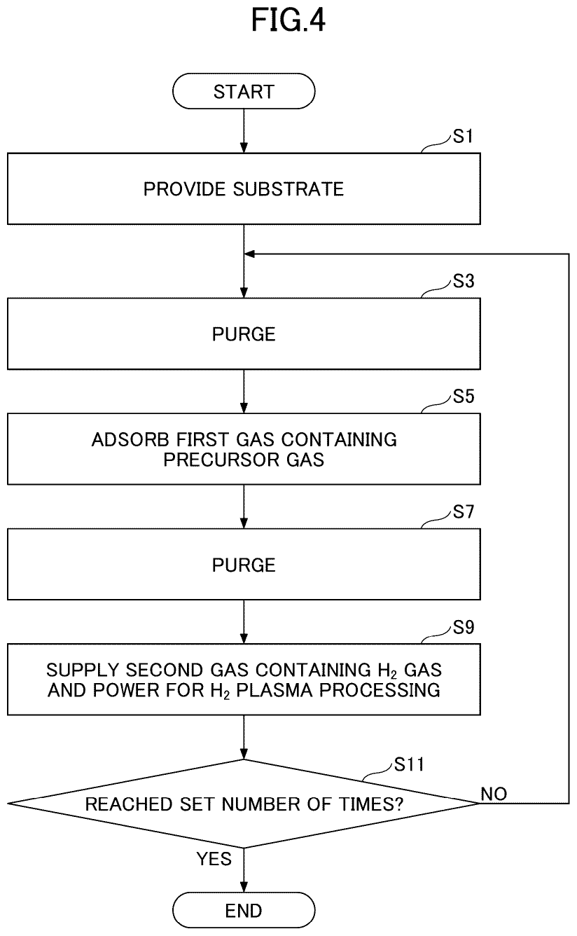

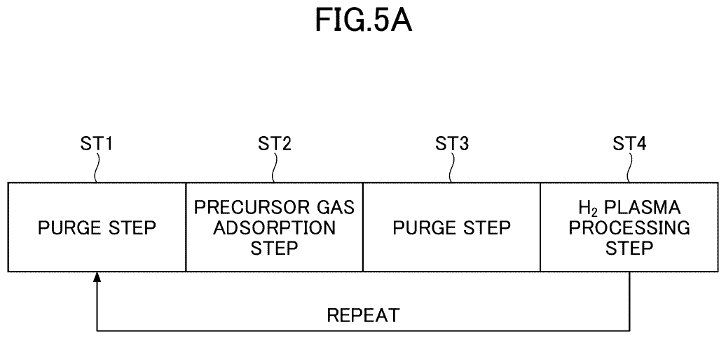

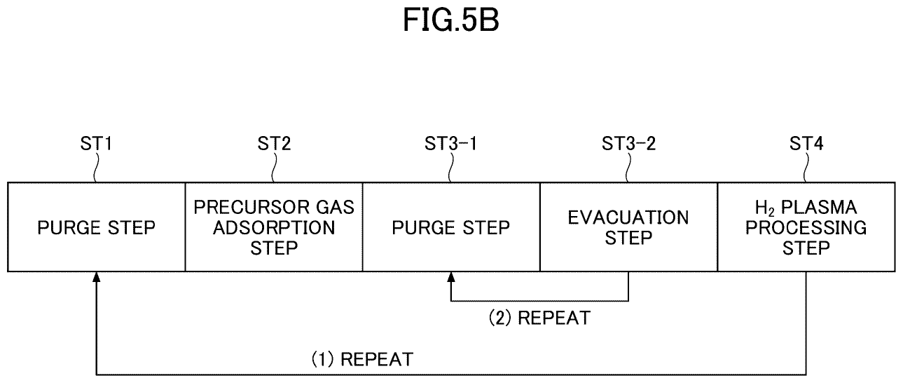

The SiCN film-forming method according to the embodiment will be described with reference to FIG. 4 and FIGS. 5A and 5B. FIG. 4 is a flowchart illustrating an example of the SiCN film-forming method according to the embodiment. FIG. 5A is a diagram illustrating an example of the SiCN film-forming method according to the embodiment. FIG. 5B is a diagram illustrating a modified example of the SiCN film-forming method according to the embodiment.

The SiCN film-forming method is, for example, an atomic layer deposition (ALD) process performed in the plasma processing apparatus 1 illustrated in FIG. 1, and is controlled by the controller 130. According to the SiCN film-forming method according to the embodiment illustrated in FIG. 4, in step S1, the controller 130 opens the gate valve 18, transfers the substrate W into the processing chamber 10 of the plasma processing apparatus 1 from the transfer opening 17, and places the substrate W at the stage 11.

Next, in step S3, the controller 130 purges the interior of the processing chamber 10 (FIG. 5A: a purge step ST1). The controller 130 supplies an inert gas, such as an Ar gas or the like, into the processing chamber 10, and performs control to purge the interior of the processing chamber 10 for 0.1 seconds to 60 seconds while the gas is being exhausted by the exhauster 16. In this manner, by exhausting the internal gas of the processing chamber 10, the interior of the processing chamber 10 is conditioned. This purge step is an example of the second purge step of purging the interior of the processing chamber 10 after “H₂ plasma processing step (ST4)” yet before “precursor gas adsorption step (ST2)” subsequently to the repeated processing performed at the second time described below. The “precursor gas adsorption step (ST2)” is an example of the “adsorption layer-forming step”, and the “H₂ plasma processing step (ST4)” is an example of the “SiCN film-forming step”.

Next, in step S5, the controller 130 supplies the first gas containing the precursor gas into the processing chamber 10, and adsorbs the first gas onto the substrate W (FIG. 5A: the precursor gas adsorption step ST2). For example, HMCTS is supplied as the precursor gas, and at least one of an Ar gas, an He gas, or an N₂ gas is supplied into the processing chamber 10 for 0.1 seconds to 60 seconds as a gas other than the precursor gas contained in the first gas. Thus, the precursor is adsorbed onto the substrate W, thereby forming the adsorption layer having the Si—N bond and the Si—C bond over the substrate W.

Next, in step S7, the controller 130 purges the interior of the processing chamber 10 (FIG. 5A: a purge step ST3). The controller 130 supplies an inert gas, such as an Ar gas or the like, into the processing chamber 10, and performs control to purge the interior of the processing chamber 10 for 0.1 seconds to 60 seconds while the gas is being exhausted by the exhauster 16. In this manner, by exhausting the internal gas of the processing chamber 10, the interior of the processing chamber 10 is conditioned. This purge step is an example of the first purge step of purging the interior of the processing chamber 10 after “precursor gas adsorption step (ST2)” yet before “H₂ plasma processing step (ST4)”.

Next, in step S9, the controller 130 supplies the second gas containing the H₂ gas into the processing chamber 10, supplies power of UHF waves, exposes the substrate W to the H₂ plasma, and causes the substrate W to react with the adsorption layer to form the SiCN film (FIG. 5A: the H₂ plasma processing step ST4). For example, an H₂ gas is supplied as the second gas, and at least one of an Ar gas, an He gas, or an No gas is supplied into the processing chamber 10 for 0.1 seconds to 60 seconds. By this, the second gas containing the H₂ gas is supplied, and the substrate W is exposed to the H₂ plasma and reacts with the adsorption layer, thereby forming the SiCN film into which the Si—C bond and the Si—N bond are introduced. The moiety R containing carbon (C) other than the C contained in the Si—C bond and the Si—N bond is cleaved by ion energy in the H₂ plasma. The reaction of the adsorption layer with the H₂ plasma leaves Si—N of Si—NH—R, and cleaves the moiety R to remove the carbon (C) contained in the moiety R. As a result, the Si—C bond and the Si—N bond are introduced from the precursor gas into the SiCN film, and it is possible to form the SiCN film having high film quality.

Next, in step S11, the controller 130 determines whether or not the process has been performed a set number of times n, and repeatedly performs steps S3 to S9 until the set number of times n is reached. If the controller 130 determines in step S11 that the set number of times has been reached, the controller 130 ends the present process.

### Modified Example

FIG. 5B is a diagram illustrating a modified example of the SiCN film-forming method according to the embodiment. Steps ST1, ST2, ST3-1, and ST4 in FIG. 5B involve performing the same processing as in steps ST1, ST2, ST3, and ST4 in FIG. 5A. The present modified example performs, in addition to these steps ST, step ST3-2, which is not illustrated in FIG. 5A.

That is, step ST3-2 of evacuating the interior of the processing chamber 10 may be further performed after the purge step of ST3-1 yet before the H₂ plasma processing step of ST4. In this evacuating step, the supply of the purge gas is stopped, and the internal pressure of the processing chamber 10 is controlled by the exhauster 16 to reach a desired degree of vacuum. Steps ST1, ST2, ST3-1, ST3-2, and ST4 may be repeatedly performed a set number of times (e.g., 100 times) (repeat of (1) in FIG. 5B). In this case, every time steps ST1, ST2, ST3-1, ST3-2, and ST4 are performed once, steps ST3-1 and ST3-2 may be performed a predetermined number of times (e.g., twice) (repeat of (2) in FIG. 5B).

Process conditions for the SiCN film-forming method illustrated in FIGS. 5A and 5B are as follows. However, the process conditions shown below are an example, and are by no means a limitation.

### [Experiment 1]

In Experiment 1, the film quality of the SiCN films formed by the SiCN film-forming method described above was studied while changing a pressure, and gas species of the precursor gas.

### <Process Conditions>

First gas: HMCTS, HMCTZ, BTBAS-MS, or TMSI (precursor gas)

Second gas: at least one of an H₂ gas, an Ar gas, an He gas, or an N₂ gas

Substrate temperature: 100° C. or higher and 450° C. or lower

Internal pressure of processing chamber: 10 Pa or higher 400 Pa or lower

Gap between the top wall 10a and the stage 11: 10 mm or greater and 100 mm or less

Frequency of UHF waves: 40 MHz or higher and 3 GHZ or lower

Power of UHF waves: 50 W or higher and 5,000 W or lower

### [Experimental Results]

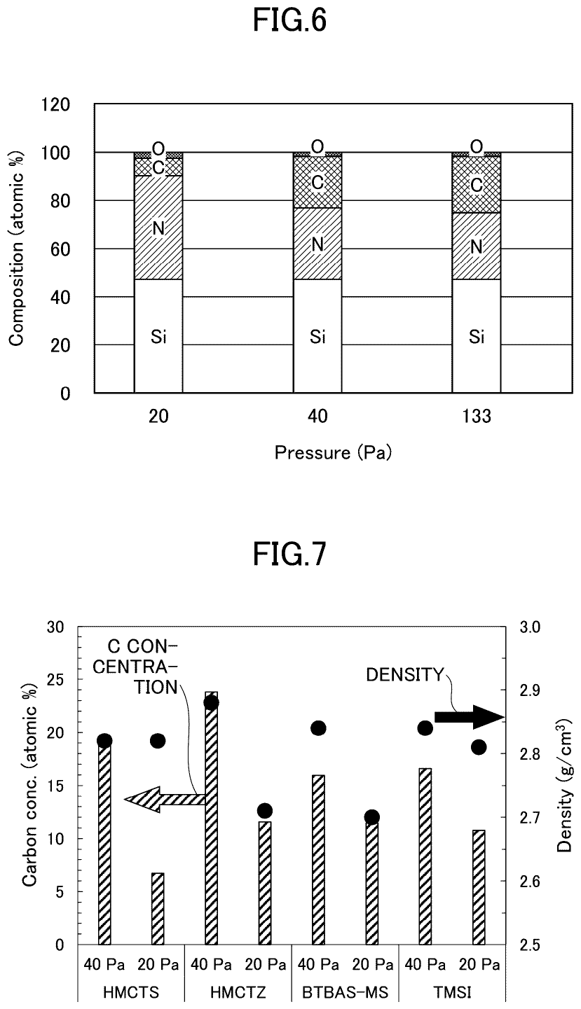

The film quality of the SiCN films formed by the SiCN film-forming method will be described with reference to FIGS. 6 to 9. FIG. 6 is a diagram illustrating an example of compositions of the SiCN films and experimental results of pressure dependencies. Here, the SiCN films were formed by the SiCN film-forming method illustrated in FIG. 4 using HMCTS as the precursor gas.

The horizontal axis of FIG. 6 indicates the internal pressure of the processing chamber 10, and the vertical axis of FIG. 6 indicates the composition of the formed SiCN film. The internal pressure of the processing chamber 10 was set to 20 Pa, 40 Pa, or 133 Pa in the adsorption layer-forming step using the first gas containing at least the precursor, and the SiCN film-forming step.

Based on the obtained results, carbon (C) was contained in the film at any levels of pressure, i.e., 20 Pa, 40 Pa, and 133 Pa. According to the SiCN film-forming method illustrated in FIG. 4, carbon (C) in the moiety R was removed during film formation. Therefore, the presence of carbon (C) in the film indicates that the Si—C bond contained in the precursor gas was introduced into the SiCN film.

Also, nitrogen (N) was contained in the film at any levels of pressure, i.e., 20 Pa, 40 Pa, and 133 Pa. That is, the Si—N bond contained in the precursor gas was introduced into the SiCN film.

Also, the concentration of carbon (C) contained in the SiCN film changed in accordance with the internal pressure of the processing chamber 10. Based on the results illustrated in FIG. 6, when the internal pressure of the processing chamber 10 was low, i.e., about 20 Pa, high ion energy was applied to the substrate W, and this increased a probability that the Si—C bond would be cleaved.

FIG. 7 is a diagram illustrating a relationship between the carbon concentration of the SiCN films and the film density of the SiCN films. Here, the SiCN films were formed by the SiCN film-forming method illustrated in FIG. 4 using HMCTS and other precursor gases.

The horizontal axis of FIG. 7 indicates the internal pressure of the processing chamber 10 for different precursor gases. The left vertical axis of FIG. 7 indicates the carbon concentration of the formed SiCN films, and the right vertical axis of FIG. 7 indicates the film density of the formed SiCN films. The internal pressure of the processing chamber 10 was set to 20 Pa or 40 Pa in the adsorption layer-forming step using the first gas containing at least the precursor, and the SiCN film-forming step.

Based on the obtained results, the carbon concentration of the SiCN films was higher at 40 Pa than at 20 Pa for any type of the precursor gases. According to the SiCN film-forming method illustrated in FIG. 4, carbon (C) in the moiety R was removed during film formation. Therefore, the presence of carbon (C) in the film indicates that the Si—C bond contained in the precursor gas was introduced into the SiCN films.

Also, when the pressure was set to a low pressure (20 Pa) regardless of the type of the precursor gas used, the carbon concentration of the SiCN films decreased, and the film density of the SiCN films decreased.

Therefore, in the adsorption layer-forming step and the SiCN film-forming step using the first gas containing the precursor, it is preferable to control the internal pressure of the processing chamber 10 to be in a range of 10 Pa or higher and 400 Pa or lower. This enables introduction of at least one of the Si—C bond or the Si—N bond contained in the precursor gas. As a result, it is possible to form the SiCN film having film quality by the presence of the Si—C bond in the SiCN film. Also, it is preferable to further reduce ion energy to avoid cleaving the Si—C bond, in addition to controlling the internal pressure of the processing chamber 10 to be an appropriate pressure in the above pressure range. Further, UHF waves having a frequency of 40 MHz or higher are preferably used to generate a high-density plasma. This can further improve the film quality of the SiCN film.

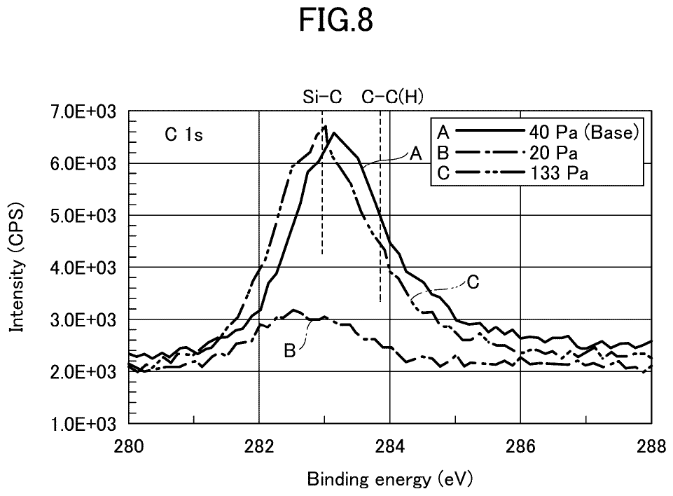

FIG. 8 is a diagram illustrating XPS spectra measured through X-ray photoelectron spectroscopy (XPS) of the SiCN films. Here, the SiCN films were formed by the SiCN film-forming method illustrated in FIG. 4 in which HMCTS was used as the precursor gas. In the experiments of FIG. 8, the SiCN films were formed by the SiCN film-forming method illustrated in FIG. 4 under the above process conditions.

The horizontal axis of FIG. 8 indicates binding energy (eV), and the vertical axis of FIG. 8 indicates an intensity (CPS) of the XPS spectra. Line A in FIG. 8 shows a state of the binding energy in the XPS spectrum of the SiCN film, in which the SiCN film formed by controlling the interior of the processing chamber 10 to be 40 Pa is a base. Line B shows a state of the binding energy in the XPS spectrum of the SiCN film formed by controlling the interior of the processing chamber 10 to be 20 Pa. Line C shows a state of the binding energy in the XPS spectrum of the SiCN film formed by controlling the interior of the processing chamber 10 to be 133 Pa.

Based on the illustrated results, according to the binding energy in the XPS spectrum indicated by the line C, in which the interior of the processing chamber 10 was at 133 Pa, the peak of the XPS spectrum indicating the Si—C bond in the measured SiCN film was at a high position in the same manner as in the peak of the base, i.e., the line A, indicating that a large number of Si—C bonds were introduced into the SiCN film in the same manner as in the base, i.e., the line A. Also, the binding state of the carbon (C) in the SiCN film was mainly the Si—C bond, and some were C—C bonds and/or C—H bonds (C—C(H) in FIG. 8). Further, the C—C(H) peak of the SiCN film in the line C was lower than that of the base, i.e., the line A, and the film quality was better than the film quality in the case of the base.

The peak of the XPS spectrum of the line B was low for both the Si—C bond and the C—C(H) bond in the measured SiCN film, and the Si—C bond introduced into the SiCN film was less than that in the cases of the line A and the line C. Based on the results illustrated in FIG. 8, when the internal pressure of the processing chamber 10 was low, i.e., about 20 Pa, high ion energy was applied to the substrate W, and this increased a probability that the Si—C bond would be cleaved.

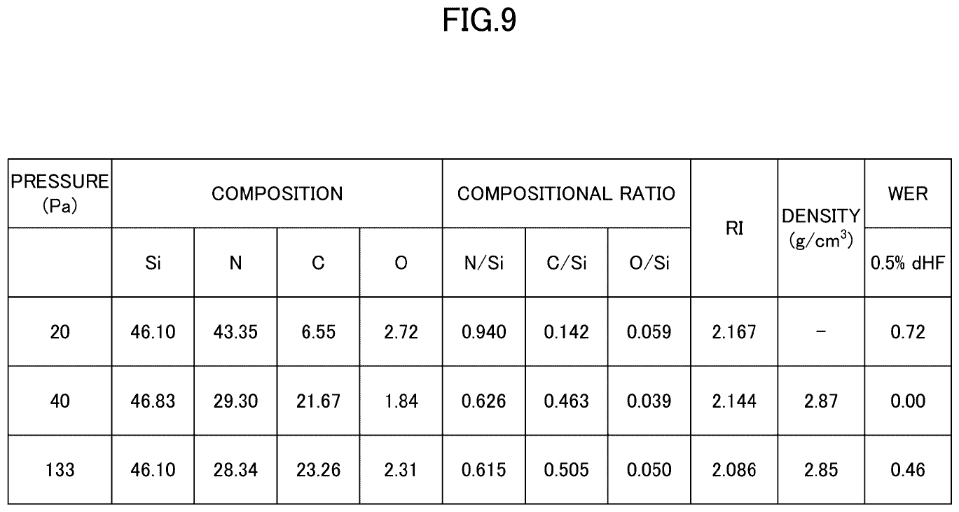

FIG. 9 is a diagram illustrating an example of experimental results of the compositions and film properties of the SiCN films. Here, the SiCN films were formed by the SiCN film-forming method illustrated in FIG. 4 in which HMCTS was used as the precursor gas. In the experiments of FIG. 9, the SiCN films were formed by the SiCN film-forming method illustrated in FIG. 4 under the above process conditions.

FIG. 9 is a diagram illustrating the internal pressure of the processing chamber 10 during film formation, as well as the composition, compositional ratio, RI, film density, and WER (wet etch rate) of the SiCN films. As illustrated in FIG. 9, according to the SiCN film-forming method illustrated in FIG. 4, the Si—C bond and the Si—N bond of the precursor gas were introduced into the SiCN films at any levels of pressure as illustrated in the composition and compositional ratio of the SiCN films. RI was substantially the same at any levels of pressure, and there was no substantial change.

When the pressure was 40 Pa or 133 Pa, the carbon (C) content of the SiCN film was 20% or more, which was 3 times or more that at 20 Pa. Therefore, although the internal pressure of the processing chamber 10 is preferably controlled to be 10 Pa or higher and 400 Pa or lower, the internal pressure of the processing chamber 10 is more preferably controlled to be 40 Pa or higher.

In general, the higher the C content of the SiCN film, the lower the film density, and the higher the film density, the better the film quality. For example, in an ALD apparatus configured to perform a batch-type thermal process, the film density becomes about 2.6 when the C content of the SiCN film reaches about 128. According to the SiCN film-forming method illustrated in FIG. 4, when the internal pressure of the processing chamber 10 was 40 Pa or 133 Pa, the film density (g/cm³) was 2.8 or more even if the C content of the SiCN film was 20% or more, i.e., the high-density SiCN film was formed.

The WER (wet etch rate) indicates an amount in which hydrofluoric acid can scrape the SiCN film for one minute (angstrom/min) at a concentration of 0.5%. The SiCN films were not significantly scraped at any levels of the internal pressure of the processing chamber 10, i.e., 20 Pa, 40 Pa, and 133 Pa. That is, the SiCN film formed by the SiCN film-forming method illustrated in FIG. 4 had satisfactory film properties including etching resistance (hydrofluoric acid resistance).

### [Experiment 2]

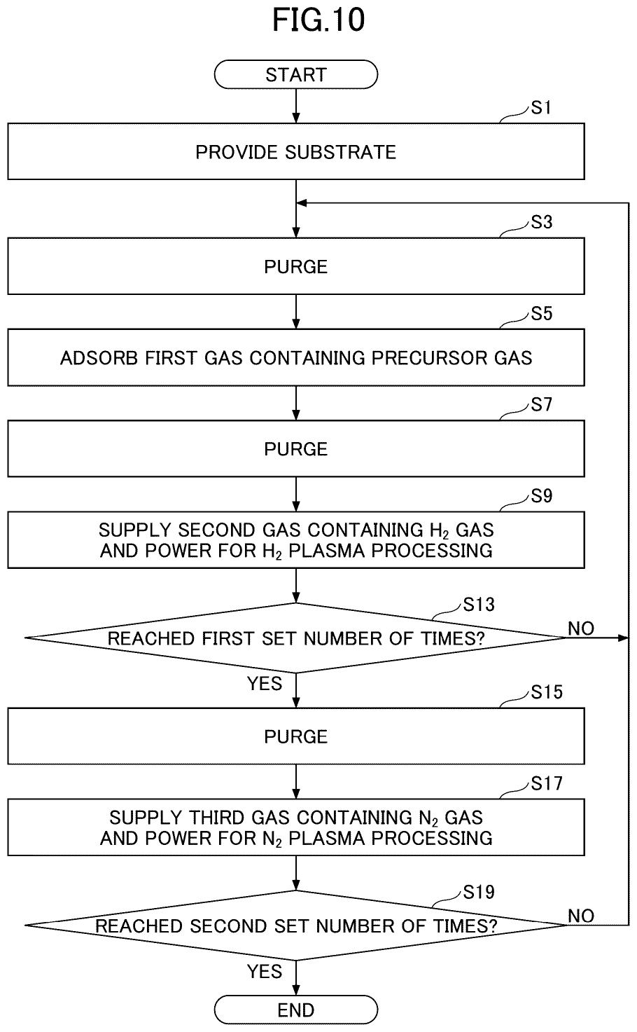

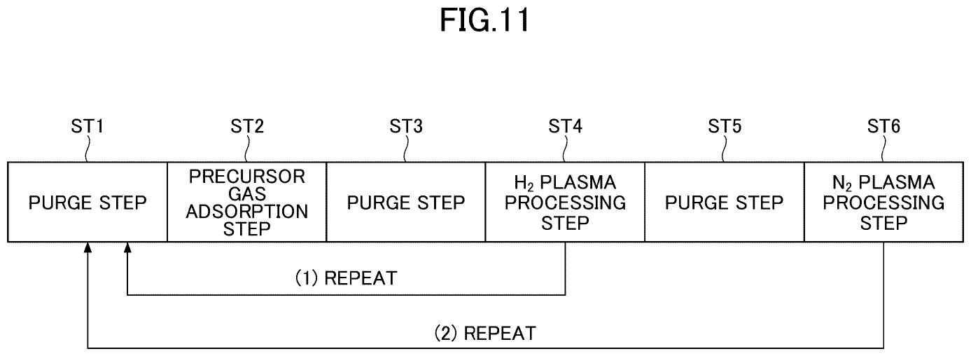

Next, an experiment was conducted to control the carbon concentration of the SiCN film. FIG. 10 is a flowchart illustrating an example of an SiCN film-forming method used in the present experiment. FIG. 11 is a diagram illustrating an example of an SiCN film-forming method used in the present experiment.

In the SiCN film-forming method illustrated in FIG. 10, when a process of ST1 to ST4 in FIG. 11 is repeatedly performed a first set number of times, the H₂ plasma processing step (ST4) is performed once at a second set number of times, which is less than the first set number of times, and then the N₂ plasma processing step (ST6) is performed after the purge step (ST5). The N₂ plasma processing is an example of a modifying step of supplying, into the processing chamber 10, a third gas containing an N₂ gas and VHF or UHF wave power to generate an N₂ plasma, and exposing the substrate W to the N₂ plasma for modification. This modifying step is performed at a predetermined frequency while the process of ST1 to ST4 in FIG. 11 is repeatedly performed.

First, in step S1, the controller 130 opens the gate valve 18, transfers the substrate W from the transfer opening 17, and places the substrate W at the stage 11. Next, in step S3, the controller 130 purges the interior of the processing chamber 10 (FIG. 11: ST1). For example, the controller 130 supplies an inert gas, such as an Ar gas or the like, into the processing chamber 10, and performs control to purge the interior of the processing chamber 10 for 0.1 seconds to 60 seconds while the gas is being exhausted by the exhauster 16. By this, the interior of the processing chamber 10 is conditioned. This purge step is an example of the second purge step.

Next, in step S5, the controller 130 supplies a first gas containing a precursor gas into the processing chamber 10, and adsorbs the first gas onto the substrate W (FIG. 11: ST2). For example, HMCTS is supplied as the precursor gas, and at least one of an Ar gas, a He gas, or an N₂ gas is supplied into the processing chamber 10 for 0.1 seconds to 60 seconds as a gas other than the precursor gas contained in the first gas. Thus, the precursor is adsorbed onto the substrate W, thereby forming the adsorption layer having the Si—N bond and the Si—C bond over the substrate W.

Next, in step S7, the controller 130 purges the interior of the processing chamber 10 (FIG. 11: ST3). For example, the controller 130 supplies an inert gas, such as an Ar gas or the like, into the processing chamber 10, and performs control to purge the interior of the processing chamber 10 for 0.1 seconds to 60 seconds while the gas is being exhausted by the exhauster 16. By this, the interior of the processing chamber 10 is conditioned. This purge step is an example of the first purge step.

Next, in step S9, the controller 130 supplies a second gas containing an H₂ gas into the processing chamber 10, supplies UHF wave power into the processing chamber 10, exposes the substrate W to an H₂ plasma, and causes the substrate W to react with the adsorption layer, thereby forming an SiCN film (FIG. 11: ST4). For example, an H₂ gas is supplied as the second gas, and at least one of an Ar gas, an He gas, or an N₂ gas is supplied into the processing chamber 10 for 0.1 seconds to 60 seconds. By this, the second gas containing the H₂ gas is supplied, and the substrate W is exposed to the H₂ plasma and reacts with the adsorption layer, thereby forming the SiCN film into which the Si—C bond and the Si—N bond are introduced. The moiety R containing carbon (C) other than the C contained in the Si—C bond is cleaved by ion energy in the H₂ plasma. The reaction of the adsorption layer with the H₂ plasma leaves Si—N of Si—NH—R, and cleaves the moiety R to remove the carbon (C) contained in the moiety R. As a result, the carbon of the SiCN film forms the Si—C bond, and it is possible to form the SiCN film having high film quality.

Next, in step S13, the controller 130 determines whether or not the first set number of times has been reached. If the first set number of times has not been reached, the controller 130 immediately causes the process to return to step S3, and performs the process subsequent to step S3.

If the first set number of times has been reached in step S13 and the process proceeds to step S15, the controller 130 purges the interior of the processing chamber 10 (FIG. 11: ST5). For example, the controller 130 supplies an inert gas, such as an Ar gas or the like, into the processing chamber 10, and performs control to purge the interior of the processing chamber 10 for 0.1 seconds to 60 seconds while the gas is being exhausted by the exhauster 16. By this, the interior of the processing chamber 10 is conditioned. This purge step is an example of a third purge step.

Next, in step S17, the controller 130 supplies a third gas containing an N₂ gas into the processing chamber 10, supplies UHF wave power into the processing chamber 10, and exposes the substrate W to an N₂ plasma to modify the SiCN film (FIG. 11: ST6). As the third gas, at least one of an Ar gas, an He gas, or an N₂ gas is supplied as a gas other than the N₂ gas into the processing chamber 10 for 0.1 seconds to 60 seconds. This supplies the third gas containing the N₂ gas, exposes the substrate W to the N₂ plasma, causes the substrate W to react with the adsorption layer, and modifies the SiCN film. Generation of the N₂ plasma is not limited to being by application of UHF wave power, but may be performed, for example, by application of VHF wave power.

Next, in step S19, the controller 130 determines whether or not the second set number of times has been reached. The second set number of times is set to be less than the first set number of times. As examples, the first set number of times is set to be 5 times to 300 times, and the second set number of times is set to be 1 time to 30 times. However, these are by no means limitations. Step S17 may be performed at a predetermined frequency during repetition of steps S3 to S9. If the second set number of times has not been reached, the controller 130 immediately causes the process to return to step S3, and performs the process subsequent to step S3. If it is determined that the second set number of times has been reached, the present process ends.

Main process conditions of the above-described SiCN film forming method for forming the SiCN film are as follows.

### <Process Conditions>

First gas: HMCTS, HMCTZ, BTBAS-MS, or TMSI (precursor gas)

Second gas: an H₂ gas, and at least one of an Ar gas, an He gas, or an N₂ gas

Third gas: N₂ gas

Substrate temperature: 100° C. or higher and 450° C. or lower

Internal pressure of processing chamber: 10 Pa or higher and 400 Pa or lower

Gap between the top wall 10a and the stage 11: 10 mm or greater and 100 mm or less

Frequency of UHF waves: 40 MHz or higher and 3 GHz or lower

Power of UHF waves: 50 W or higher and 5,000 W or lower

### [Experimental Results]

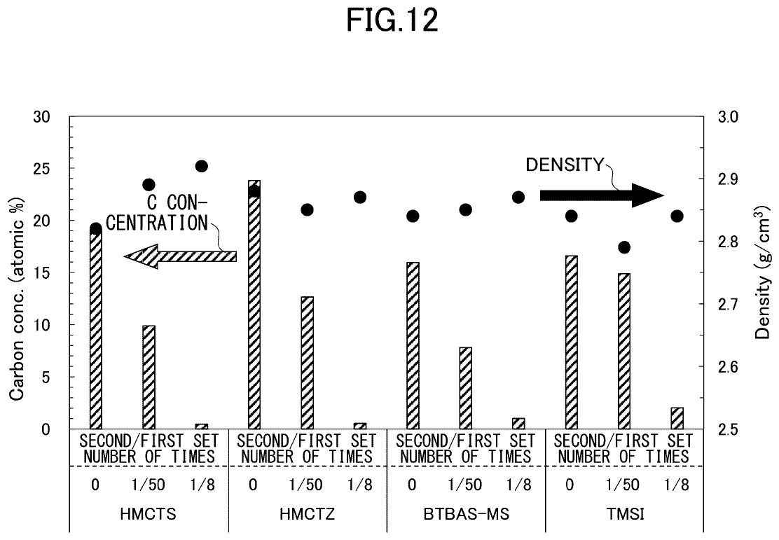

FIG. 12 is a diagram illustrating a relationship between a carbon concentration and a film density of the SiCN films. Here, the SiCN films were formed by the SiCN film-forming method illustrated in FIG. 10 in which the precursor gases, i.e., HMCTS, HMCTZ, BTBAS-MS, and TMSI, were used.

The horizontal axis of FIG. 12 indicates frequencies of modification with the N₂ plasma processing for different precursor gases, and the left vertical axis of FIG. 12 indicates a carbon concentration (carbon conc.) of the formed SiCN film. The right vertical axis of FIG. 12 indicates the film density of the formed SiCN film. The frequencies of modification were set to 0 (no N₂ plasma processing was performed), 1/50, and ⅛ as ratios of the number of the N₂ plasma processes to the number of the H₂ plasma processes (the second set number of times/the first set number of times; see FIG. 10). The first set number of times is the number of repeats (1) of the H₂ plasma processing step (ST4) illustrated in FIG. 11, and the second set number of times is the number of repeats (2) of the N₂ plasma processing step (ST6) illustrated in FIG. 11.

As a result, the carbon concentration of the SiCN film could be adjusted and controlled by changing the frequency of modification with the N₂ plasma.

By performing the modification processing with the N₂ plasma (FIG. 10: S17), the film quality of the SiCN film can be improved compared to a case in which the modification processing with the N₂ plasma is not performed. This indicates that the film quality can be maintained while controlling the carbon concentration of the SiCN film to a desired concentration.

As described above, according to the SiCN film-forming methods of the first and second embodiments, the Si—C bond of the precursor gas can be introduced into the SiCN film formed over the substrate. This can form an SiCN film having high film quality. Also, the film quality of the SiCN film can be further improved by generating the high-frequency plasma having a high plasma density using VHF or UHF waves having a frequency of 100 MHz or higher and 3 GHz or lower.

According to the SiCN film-forming method in which the modification processing with the N₂ plasma is performed, the N₂ plasma processing is performed at a predetermined frequency for adjusting the C content of the SiCN film. This can successfully achieve both adjustment of the N and C concentrations of the SiCN film, and an improvement in the film quality of the SiCN film.

The SiCN film-forming method and the plasma processing apparatus according to the embodiments disclosed herein should be considered to be illustrative and non-limiting in all respects. The embodiments can be modified and improved in various forms without departing from the scope and intent of claims recited. The matters described in the above embodiments can have other configurations unless there is a contradiction, and can be combined unless there is a contradiction.

The plasma processing apparatus of the present disclosure is applicable to any type of apparatuses of a capacitively coupled plasma (CCP) type, an inductively coupled plasma (ICP) type, a radial line slot antenna (RLSA) type, an electron cyclotron resonance plasma (ECR) type, and a helicon wave plasma (HWP) type.

According to an aspect of the present disclosure, an Si—C bond of a precursor gas can be introduced into a film formed over a substrate.

What is claimed is:

1. A silicon carbonitride film-forming method, comprising:
(a) providing a substrate in a processing chamber;
(b) supplying, into the processing chamber, a first gas containing a precursor gas having an Si—N bond and an Si—C bond, thereby forming an adsorption layer over the substrate, wherein the Si—N bond and the Si—C bond are not activated in the formation of the adsorption layer;
(c) first purging of purging an interior of the processing chamber after (b); and
(d) supplying, into the processing chamber, a second gas containing a hydrogen gas and power of VHF waves or UHF waves, thereby generating a plasma, wherein the substrate is exposed to the plasma and reacts with the adsorption layer to form a silicon carbonitride (SiCN) film, and at least one of the Si—C bond or the Si—N bond of the adsorption layer is introduced into the SiCN film; and
(e) second purging of purging the interior of the processing chamber after (d), wherein
(b) to (e) are repeatedly performed.

2. The silicon carbonitride film-forming method according to claim 1, wherein
the precursor gas is free of an Si—Si bond.

3. The silicon carbonitride film-forming method according to claim 1, wherein
a frequency of the VHF waves or the UHF waves is 100 MHz or higher and 3 GHz or lower.

4. The silicon carbonitride film-forming method according to claim 1, wherein
in (b) and (d), an internal pressure of the processing chamber is 10 Pa or higher and 400 Pa or lower.

5. The silicon carbonitride film-forming method according to claim 1, wherein
the second gas contains an inert gas.

6. The silicon carbonitride film-forming method according to claim 5, wherein
the inert gas is at least one of an Ar gas, an He gas, or an N₂ gas.

7. The silicon carbonitride film-forming method according to claim 1, further comprising:
(f) evacuating the interior of the processing chamber after (c) yet before (d).

8. The silicon carbonitride film-forming method according to claim 7, wherein
(c) and (f) are repeatedly performed a predetermined number of times, and (d) is performed.

9. The silicon carbonitride film-forming method according to claim 1, wherein
the precursor gas is at least one of HMCTS, HMCTZ, TMSI, BTBAMS, BSBAMS, BTBAES, or BTBAVS.

10. The silicon carbonitride film-forming method according to claim 1, wherein
a temperature of the substrate is 450° C. or lower.

11. The silicon carbonitride film-forming method according to claim 1, further comprising:
(g) modifying the substrate by exposing the substrate to a plasma, wherein the plasma is generated by supplying, into the processing chamber, a third gas containing a nitrogen gas and the power of the VHF waves or the UHF waves.

12. The silicon carbonitride film-forming method according to claim 11, wherein
(g) is performed at a predetermined frequency during repetition of a process of (b) to (e).

13. A plasma processing apparatus, comprising:
a processing chamber; and
a controller including a memory and a processor coupled to the memory, wherein
the processor is configured to control the silicon carbonitride film-forming method of claim 1.
